(19) United States
(12) Patent Application Publication
(10) Pub. No.: US 2025/0357909 A1
(43) Pub. Date: Nov. 20, 2025

(54) ACOUSTIC DEVICES INCORPORATING MULTILAYER VAN DER WAALS MATERIAL

(71) Applicant: Qorvo US, Inc., Greensboro, NC (US)

(72) Inventor: Robert Aigner, Ocoee, FL (US)

(21) Appl. No.: 19/097,963

(22) Filed: Apr. 2, 2025

Related U.S. Application Data
(60) Provisional application No. 63/648,707, filed on May 17, 2024.

(51) Int. Cl. H03H 9/02; G01C 19/58; H03H 9/17; H03H 9/25

(52) U.S. Cl. CPC H03H 9/02866; G01C 19/58; H03H 9/0211; H03H 9/17; H03H 9/25

(57) ABSTRACT

The present disclosure relates to acoustic devices incorporating a multilayer van der Waals (vdW) material(s). In various embodiments disclosed herein, a multilayer vdW material(s) is provided in various types of acoustic devices, such as surface acoustic wave (SAW) devices, bulk acoustic wave (BAW) devices, cross bulk acoustic resonator (XBAR) devices, and acoustic gyroscope devices, to help manipulate (e.g., separate, trap, guide, etc.) a shear acoustic wave(s) and/or a longitudinal acoustic wave(s) in the acoustic devices. By utilizing the multilayer vdW material(s), it is thus possible to improve size, thermal dissipation, and performance of the acoustic devices.

### RELATED APPLICATIONS

This application claims the benefit of U.S. provisional patent application Ser. No. 63/648,707, filed on May 17, 2024, the disclosure of which is hereby incorporated herein by reference in its entirety.

### FIELD OF THE DISCLOSURE

The technology of the disclosure relates generally to acoustic devices incorporating a multilayer van der Waals (vdW) material(s).

### BACKGROUND

Wireless devices have become increasingly common in current society. These wireless devices often rely on various acoustic devices (e.g., acoustic filters, acoustic resonators, acoustic gyroscopes, etc.) to support a variety of applications.

An acoustic device can be configured to propagate either a shear acoustic wave(s) and/or a longitudinal acoustic wave(s) in infinitely large, isotropic, and homogeneous materials. In a shear acoustic wave, a particle motion is perpendicular to a wave direction, whereas in a longitudinal acoustic wave, the particle motion is parallel to the wave direction. Typically, the shear acoustic wave has a slower velocity and a shorter wavelength, thus making a shear wave based acoustic device ideal for reducing device size. In contrast, the longitudinal acoustic wave has a faster velocity and a longer wavelength, thus making a longitudinal wave based acoustic device ideal for higher frequency operations where a wavelength that is too small is detrimental to device performance.

Barring some exceptional cases where the shear acoustic wave(s) and the longitudinal acoustic wave(s) are intermingled due to such effects as geometry, interface, discontinuity, and inhomogeneity, a vast majority of the acoustic devices will be configured to operate based on either the shear acoustic wave or the longitudinal acoustic wave. As such, it is often necessary to separate the shear acoustic wave from the longitudinal acoustic wave, or vice versa.

Multilayer van der Waals (vdW) materials, such as multilayer graphene, multilayer hexagonal boron-nitride (h-BN), multilayer transition metal-dichalcogenides (TMDCs), and multilayer transition metal carbides/nitrides (MXenes), have become increasingly popular due to some abnormal mechanical properties. FIG. 1 is a schematic diagram of an exemplary multilayer vdW material 10 that can reflect a shear acoustic wave 12 but will allow a longitudinal acoustic wave 14 to pass through. The unique property presented by the multilayer vdW material 10 is thus desirable for manipulating (e.g., separating, trapping, guiding, etc.) the shear acoustic wave(s) and/or the longitudinal acoustic wave(s) in the acoustic devices.

### SUMMARY

Aspects disclosed in the detailed description include acoustic devices incorporating a multilayer van der Waals (vdW) material(s). In various embodiments disclosed herein, the multilayer vdW material(s) is provided in various types of acoustic devices, such as surface acoustic wave (SAW) devices, bulk acoustic wave (BAW) devices, cross bulk acoustic resonator (XBAR) devices, and acoustic gyroscope devices, to help manipulate (e.g., separate, trap, guide, etc.) a shear acoustic wave(s) and/or a longitudinal acoustic wave(s) in the acoustic devices. By utilizing the multilayer vdW material(s), it is thus possible to improve size, thermal dissipation, and performance of the acoustic devices.

In one aspect, a SAW device is provided. The SAW device includes a substrate. The SAW device also includes a dielectric layer. The dielectric layer is provided on the substrate. The SAW device also includes one or more interdigital transducers (IDTs). The one or more IDTs are provided on the substrate. The one or more IDTs are configured to induce a shear acoustic wave in the substrate. The SAW device also includes a multilayer vdW material. The multilayer vdW material is provided in the dielectric layer. The multilayer vdW material is configured to trap the shear acoustic wave within the dielectric layer.

In another aspect, a guided SAW device is provided. The guided SAW device includes a substrate. The guided SAW device also includes a piezoelectric layer. The piezoelectric layer is provided over the substrate. The guided SAW device also includes one or more IDTs. The one or more IDTs are provided on the piezoelectric layer. The one or more IDTs are configured to induce a shear acoustic wave in the piezoelectric layer. The guided SAW device also includes a multilayer vdW material. The multilayer vdW material is provided between the piezoelectric layer and the substrate to block the shear acoustic wave from entering the substrate.

In another aspect, a BAW device is provided. The BAW device includes a substrate. The BAW device also includes a bottom electrode. The bottom electrode is provided on the substrate. The BAW device also includes a bottom multilayer vdW material. The bottom multilayer vdW material is provided on the bottom electrode. The BAW device also includes a piezoelectric layer. The piezoelectric layer is provided on the bottom multilayer vdW material. The BAW device also includes a top multilayer vdW material. The top multilayer vdW material is provided on the piezoelectric layer. The BAW device also includes a top electrode. The top electrode is provided on the top multilayer vdW material.

In another aspect, an XBAR device is provided. The XBAR device includes a substrate. The XBAR device also includes a bottom multilayer vdW material. The bottom multilayer vdW material is provided on the substrate. The XBAR device also includes a piezoelectric layer. The piezoelectric layer is provided on the bottom multilayer vdW material. The XBAR device also includes a top multilayer vdW material. The top multilayer vdW material is provided on the piezoelectric layer. The XBAR device also includes one or more electrodes. The one or more electrodes are provided on the top multilayer vdW material.

In another aspect, an acoustic gyroscope device is provided. The acoustic gyroscope device includes a substrate. The acoustic gyroscope device also includes a sensing acoustic resonator. The sensing acoustic resonator is provided on the substrate. The acoustic gyroscope device also includes a dielectric layer. The dielectric layer is provided over the sensing acoustic resonator. The acoustic gyroscope device also includes a bottom multilayer vdW material. The bottom multilayer vdW material is provided on the dielectric layer. The acoustic gyroscope device also includes a driving acoustic resonator. The driving acoustic resonator is provided on the bottom multilayer vdW material. The acoustic gyroscope device also includes a top multilayer vdW material. The top multilayer vdW material is provided over the driving acoustic resonator.

In another aspect, a wireless device is provided. The wireless device includes one or more acoustic devices. The one or more acoustic devices are selected from the group consisting of a SAW device, a guided SAW device, a BAW device, an XBAR device, and an acoustic gyroscope device.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary multilayer van der Waals (vdW) material;

FIGS. 2A and 2B are schematic diagrams of exemplary surface acoustic wave (SAW) devices configured according to various embodiments of the present disclosure to incorporate the multilayer vdW material of FIG. 1;

FIG. 3 is a schematic diagram of an exemplary guided SAW device configured according to another embodiment of the present disclosure to incorporate the multilayer vdW material of FIG. 1;

FIG. 4 is a schematic diagram of an exemplary bulk acoustic wave (BAW) device configured according to another embodiment of the present disclosure to incorporate the multilayer vdW material of FIG. 1;

FIG. 5 is a schematic diagram of an exemplary XBAR device configured according to another embodiment of the present disclosure to replace the air cavity in FIG. 5 with the multilayer vdW material of FIG. 1;

FIG. 6 is a schematic diagram of an exemplary acoustic gyroscope device configured according to another embodiment of the present disclosure to incorporate the multilayer vdW material of FIG. 1; and

FIG. 7 is a schematic diagram of an exemplary communication device wherein the SAW devices of FIGS. 2A-2B, the guided SAW device of FIG. 3, the BAW device of FIG. 4, the XBAR device of FIG. 5, and/or the acoustic gyroscope device of FIG. 6 can be provided.

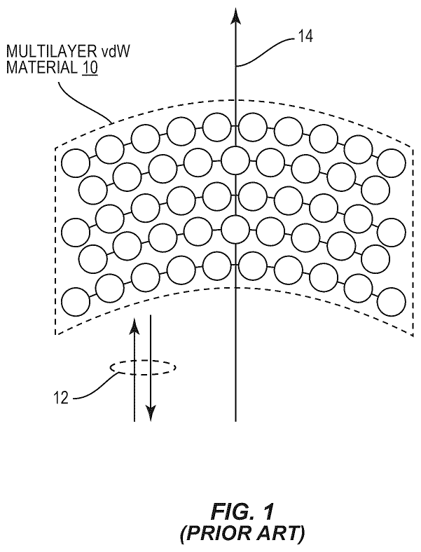

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include acoustic devices incorporating a multilayer van der Waals (vdW) material(s). In various embodiments disclosed herein, a multilayer vdW material(s) is provided in various types of acoustic devices, such as surface acoustic wave (SAW) devices, bulk acoustic wave (BAW) devices, cross bulk acoustic resonator (XBAR) devices, and acoustic gyroscope devices, to help manipulate (e.g., separate, trap, guide, etc.) a shear acoustic wave(s) and/or a longitudinal acoustic wave(s) in the acoustic devices. By utilizing the multilayer vdW material(s), it is thus possible to improve size, thermal dissipation, and performance of the acoustic devices.

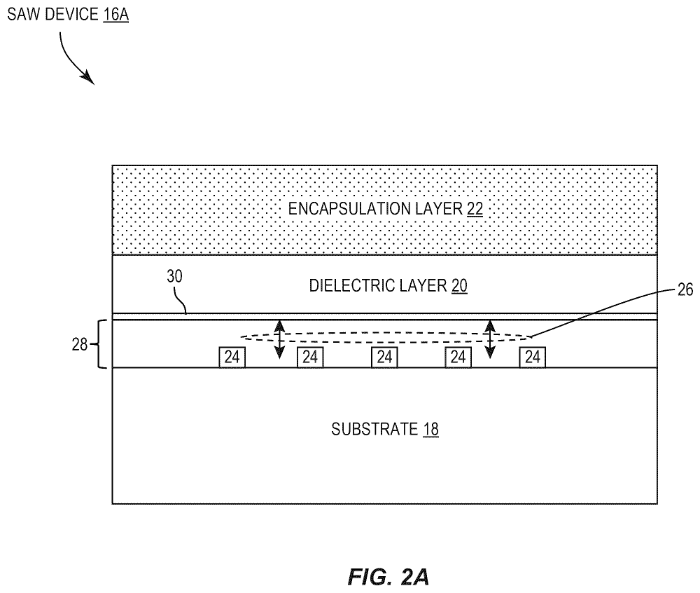

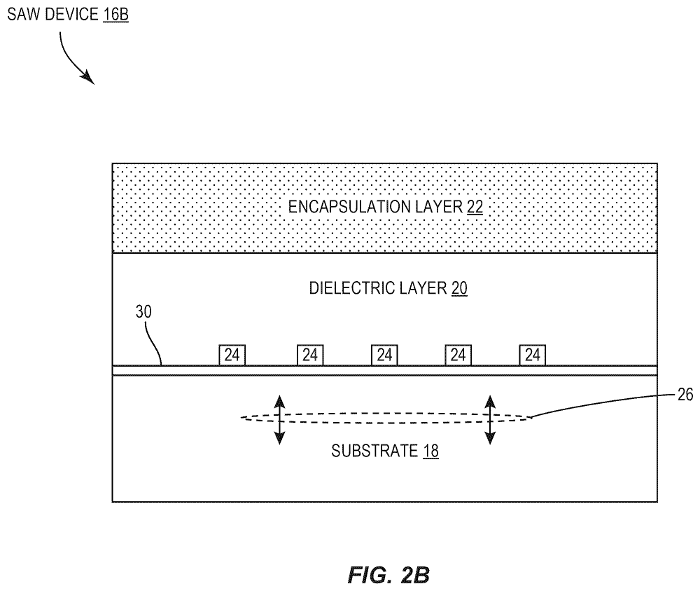

FIG. 2A is a schematic diagram of an exemplary SAW device 16A configured according to one embodiment of the present disclosure. Herein, the SAW device 16A includes a substrate 18, which can be lithium niobate (LN) or lithium tantalate (LT), as an example. The SAW device 16A also includes a dielectric layer 20, which can be silicon dioxide (SiO2), as an example. The dielectric layer 20 is provided on the substrate 18, and an encapsulation layer 22 is provided on the dielectric layer 20. The SAW device 16A also includes one or more interdigital transducers (IDTs) 24, which can induce a shear acoustic wave 26 in an active region 28 in the dielectric layer 20.

Conventionally, an air cavity (not shown) is often created using wafer-level-packaging (WLP) above the IDTs 24 to prevent acoustic energy from leaking into the encapsulation layer 22. Since the air cavity can increase height and reduce thermal dissipation, it is thus desirable to replace the air cavity in the SAW device 16A with a more desirable solution.

In this regard, a thin multilayer vdW material 30 is inserted into the dielectric layer 20, in between the IDTs 24 and the encapsulation layer 22. Herein, the thin multilayer vdW material 30 is configured to block the shear acoustic wave 26 from the encapsulation layer 22. In other words, the shear acoustic wave 26 is trapped between the thin multilayer vdW material 30 and the substrate 18. Because the thin multilayer vdW material 30 is provided above the IDTs 24, the IDTs 24 can therefore be moving IDTs.

FIG. 2B is a schematic diagram of an exemplary SAW device 16B configured according to one embodiment of the present disclosure. Common elements between FIGS. 2A and 2B are shown therein with common element numbers and will not be re-described herein.

Herein, the thin multilayer vdW material 30 is instead provided between the IDTs 24 and the substrate 18. Because the thin multilayer vdW material 30 is provided underneath the IDTs 24, the IDTs 24 can therefore be non-moving IDTs and the shear acoustic wave 26 is trapped in the substrate 18. In this regard, the IDTs 24 can be made as thick as desired without creating excessive mass loading or losses. Moreover, the thin multilayer vdW material 30 may even be inserted in between sandwiched IDTs.

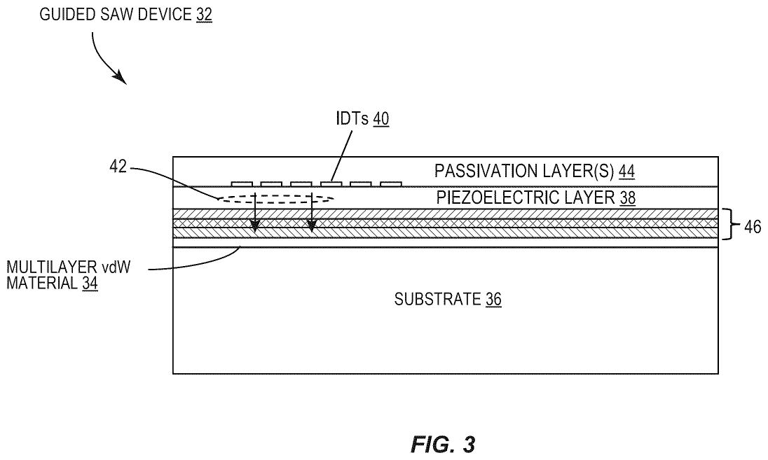

FIG. 3 is a schematic diagram of an exemplary guided SAW device 32 configured according to another embodiment of the present disclosure. Herein, the guided SAW device 32 is modified from a guided SAW device described in U.S. Pat. No. 11,309,861 B2, entitled “GUIDED SURFACE ACOUSTIC WAVE DEVICE PROVIDING SPURIOUS MODE REJECTION” (hereinafter “Patent '861”), by inserting a multilayer vdW material 34 in between a substrate 36 and a piezoelectric layer 38.

Herein, one or more IDTs 40 are provided on the piezoelectric layer 38 to induce a shear acoustic wave 42 in the piezoelectric layer 38. The multilayer vdW material 34 is provided between the piezoelectric layer 38 and the substrate 36 to block the shear acoustic wave 42 from entering the substrate 36. Notably, it may be undesirable for the multilayer vdW material 34 to be a multilayer graphene. Instead, it may be more preferrable to make the multilayer vdW material 34 with a non-conductive vdW material.

As described in Patent '861, the guided SAW device 32 may also include one or more passivation layers 44 that are provided over the IDTs 40. The guided SAW device 32 may further include one or more dielectric layers 46, which are provided between the multilayer vdW material 34 and the piezoelectric layer 38.

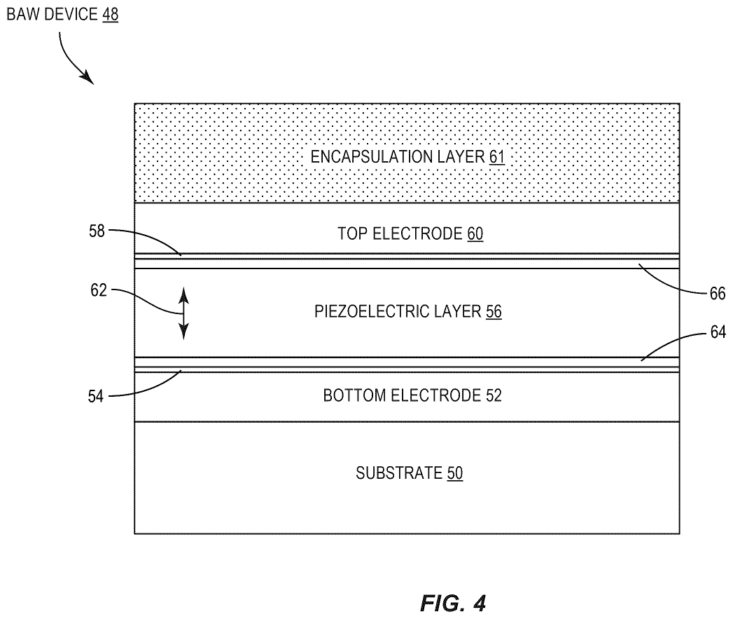

Besides using the multilayer vdW material in the SAW device 16A of FIG. 2A, the SAW device 16B of FIG. 2B, and the guided SAW device 32 of FIG. 3, it is also possible to use the multilayer vdW material in a BAW device. In this regard, FIG. 4 is a schematic diagram of an exemplary BAW device 48 configured according to another embodiment of the present disclosure.

Herein, the BAW device 48 includes a substrate 50, a bottom electrode 52, a bottom multilayer vdW material 54, a piezoelectric layer 56, a top multilayer vdW material 58, and a top electrode 60. Specifically, the bottom electrode 52 is provided on the substrate 50, the bottom multilayer vdW material 54 is provided on the bottom electrode 52, the piezoelectric layer 56 is provided on the bottom multilayer vdW material 54, the top multilayer vdW material 58 is provided on the piezoelectric layer 56, and the top electrode 60 is provided on the top multilayer vdW material 58. The BAW device 48 further includes an encapsulation layer 61 that is provided over the top electrode 60. Notably, both the bottom electrode 52 and the top electrode 60 can be made thicker to help improve electrical performance.

Notably, most BAW devices operate based on a longitudinal acoustic wave in frequencies above 1 GHz. Nevertheless, the BAW device 48 can be made to operate based on a shear acoustic wave by making the piezoelectric layer 56 suitable for shear acoustic wave operation with correct crystal orientation. In this regard, the top electrode 60 and the bottom electrode 52 can collectively induce a shear acoustic wave 62 in the piezoelectric layer 56. The top multilayer vdW material 58 and the bottom multilayer vdW material 54, on the other hand, are configured to trap the shear acoustic wave 62 within the piezoelectric layer 56.

In an embodiment, the BAW device 48 may further include a bottom high acoustic impedance layer 64 and a top high acoustic impedance layer 66, such as Tungsten or Molybdenum as an example. The bottom high acoustic impedance layer 64 may be provided between the bottom multilayer vdW material 54 and the piezoelectric layer 56, whereas the top high acoustic impedance layer 66 may be provided between the piezoelectric layer 56 and the top multilayer vdW material 58.

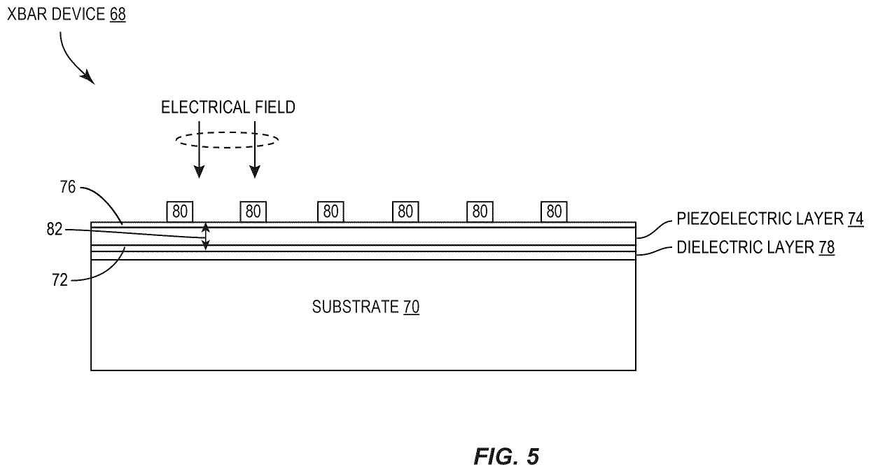

Besides using multilayer vdW material in SAW and BAW devices, it is also possible to use the multilayer vdW material in an XBAR device. In this regard, FIG. 5 is a schematic diagram of an exemplary XBAR device 68 configured according to another embodiment of the present disclosure.

Herein, the XBAR device 68 includes a substrate 70, a bottom multilayer vdW material 72, a piezoelectric layer 74, and a top multilayer vdW material 76. The bottom multilayer vdW material 72 is provided on the substrate 70, the piezoelectric layer 74 is provided on the bottom multilayer vdW material 72, and the top multilayer vdW material 76 is provided on the piezoelectric layer 74. The XBAR device 68 may also include a dielectric layer 78, which may be provided between the substrate 70 and the bottom multilayer vdW material 72.

The XBAR device 68 also includes one or more electrodes 80 that are provided on the top multilayer vdW material 76. When the electrodes 80 are excited by a lateral electrical field, a shear acoustic wave 82 is induced in the piezoelectric layer 74. In this regard, the top multilayer vdW material 76 and the bottom multilayer vdW material 72 will trap the shear acoustic wave 82 within the piezoelectric layer 74. In other words, the top multilayer vdW material 76 and the bottom multilayer vdW material 72 can prevent the shear acoustic wave 82 from entering into the substrate 70.

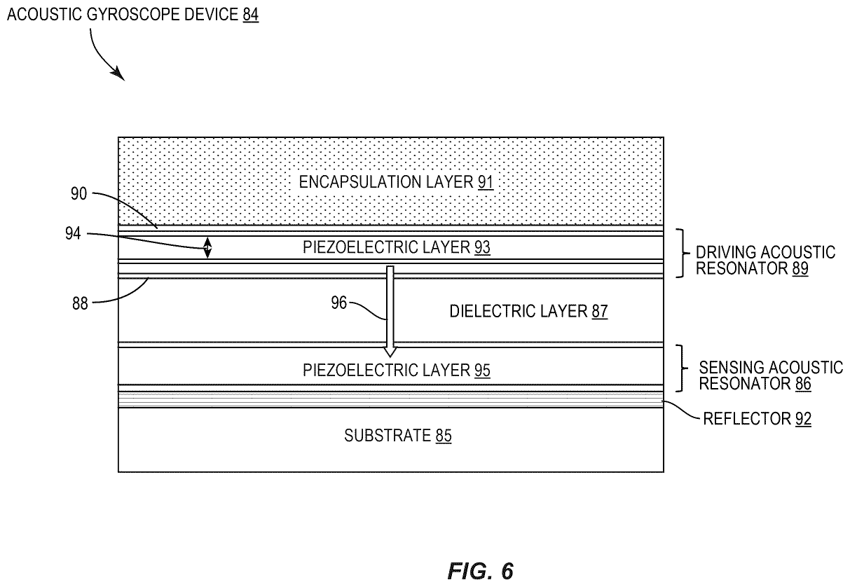

Besides using a multilayer vdW material in SAW, BAW, and XBAR devices, it is also possible to use the multilayer vdW material in an acoustic gyroscope device. In this regard, FIG. 6 is a schematic diagram of an exemplary acoustic gyroscope device 84 configured according to another embodiment of the present disclosure.

Herein, the acoustic gyroscope device 84 includes a substrate 85, a sensing acoustic resonator 86, a dielectric layer 87, a bottom multilayer vdW material 88, a driving acoustic resonator 89, and a top multilayer vdW material 90. Specifically, the sensing acoustic resonator 86 is provided on the substrate 85, the dielectric layer 87 is provided over the sensing acoustic resonator 86, the bottom multilayer vdW material 88 is provided on the dielectric layer 87, the driving acoustic resonator 89 is provided on the bottom multilayer vdW material 88, and the top multilayer vdW material 90 is provided over the driving acoustic resonator 89.

The acoustic gyroscope device 84 can further include an encapsulation layer 91 and a reflector 92. In an embodiment, the encapsulation layer 91 is provided over the top multilayer vdW material 90, whereas the reflector 92 is provided between the sensing acoustic resonator 86 and the substrate 85.

In an embodiment, the driving acoustic resonator 89 includes a respective piezoelectric layer 93 suited for a shear wave operation. Accordingly, the driving acoustic resonator 89 is configured to propagate a shear acoustic wave 94. In contrast, the sensing acoustic resonator 86 includes a respective piezoelectric layer 95 suited for a longitudinal wave operation. Accordingly, the sensing acoustic resonator 86 is configured to propagate a longitudinal acoustic wave 96.

When the driving acoustic resonator 89 detects a rotation, the driving acoustic resonator 89 converts the shear acoustic wave 94 into the longitudinal acoustic wave 96 through interaction with Coriolis force in the presence of rotation, which will then propagate to the sensing acoustic resonator 86 through the dielectric layer 87. In this regard, the top multilayer vdW material 90 and the bottom multilayer vdW material 88 will trap the shear acoustic wave 94 within the driving acoustic resonator 89 but will allow the longitudinal acoustic wave 96 to pass through the dielectric layer 87 to get to the sensing acoustic resonator 86.

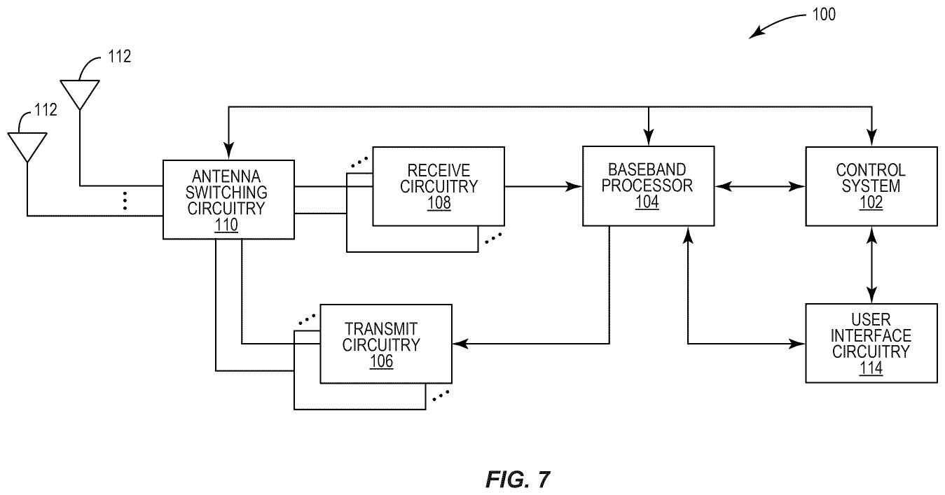

The SAW device 16A of FIG. 2A, the SAW device 16B of FIG. 2B, the guided SAW device 32 of FIG. 3, the BAW device 48 of FIG. 4, the XBAR device 68 of FIG. 5, and the acoustic gyroscope device 84 of FIG. 6 can be provided in a communication device to support the embodiments described above. In this regard, FIG. 7 is a schematic diagram of an exemplary communication device 100 wherein the SAW device 16A of FIG. 2A, the SAW device 16B of FIG. 2B, the guided SAW device 32 of FIG. 3, the BAW device 48 of FIG. 4, the XBAR device 68 of FIG. 5, and the acoustic gyroscope device 84 of FIG. 6 can be provided.

Herein, the communication device 100 can be any type of communication device, such as mobile terminal, smart watch, tablet, computer, navigation device, access point, base station (e.g., eNB, gNB), and like wireless communication devices that support wireless communications, such as cellular, wireless local area network (WLAN), Bluetooth, Ultrawideband (UWB), and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Herein, the SAW device 16A of FIG. 2A, the SAW device 16B of FIG. 2B, the guided SAW device 32 of FIG. 3, the BAW device 48 of FIG. 4, the XBAR device 68 of FIG. 5, and/or the acoustic gyroscope device 84 of FIG. 6 can be provided in almost every circuit of the communication device 100. In one example, the SAW device 16A of FIG. 2A, the SAW device 16B of FIG. 2B, the guided SAW device 32 of FIG. 3, the BAW device 48 of FIG. 4, and/or the XBAR device 68 of FIG. 5 can be provided in the transmit circuitry 106, the receive circuitry 108, and/or the antenna switching circuitry 110. In another example, the acoustic gyroscope device 84 of FIG. 6 can be provided in the control system 102 and/or user interface circuitry 114.

Those skilled in the art will recognize improvements and modifications to the embodiments of the present disclosure. All such improvements and modifications are considered within the scope of the concepts disclosed herein and the claims that follow.

What is claimed is:

1. A surface acoustic wave (SAW) device comprising:
a substrate;
a dielectric layer provided on the substrate;
one or more interdigital transducers (IDTs) provided on the substrate and configured to induce a shear acoustic wave in the substrate; and
a multilayer van der Waals (vdW) material provided in the dielectric layer and configured to trap the shear acoustic wave within the dielectric layer.

2. The SAW device of claim 1, wherein the multilayer vdW material is provided over the one or more IDTs.

3. The SAW device of claim 1, wherein the one or more IDTs are moving IDTs.

4. The SAW device of claim 1, wherein the multilayer vdW material is provided on the substrate and underneath the one or more IDTs.

5. The SAW device of claim 1, wherein the one or more IDTs are non-moving IDTs.

6. A guided surface acoustic wave (SAW) device comprising:
a substrate;
a piezoelectric layer provided over the substrate;
one or more interdigital transducers (IDTs) provided on the piezoelectric layer and configured to induce a shear acoustic wave in the piezoelectric layer; and
a multilayer van der Waals (vdW) material provided between the piezoelectric layer and the substrate to block the shear acoustic wave from entering the substrate.

7. The guided SAW device of claim 6, further comprising one or more dielectric layers provided between the multilayer vdW material and the piezoelectric layer.

8. The guided SAW device of claim 6, further comprising one or more passivation layers provided over the one or more IDTs.

9. A bulk acoustic wave (BAW) device comprising:
a substrate;
a bottom electrode provided on the substrate;
a bottom multilayer van der Waals (vdW) material provided on the bottom electrode;
a piezoelectric layer provided on the bottom multilayer vdW material;
a top multilayer vdW material provided on the piezoelectric layer; and
a top electrode provided on the top multilayer vdW material.

10. The BAW device of claim 9, further comprising:
a bottom high acoustic impedance layer provided between the bottom multilayer vdW material and the piezoelectric layer; and
a top high acoustic impedance layer provided between the piezoelectric layer and the top multilayer vdW material.

11. The BAW device of claim 9, wherein the piezoelectric layer is constructed with material suitable for a shear acoustic wave operation.

12. The BAW device of claim 9, wherein:
the top electrode and the bottom electrode are configured to collectively induce a shear acoustic wave in the piezoelectric layer; and
the top multilayer vdW material and the bottom multilayer vdW material are configured to trap the shear acoustic wave within the piezoelectric layer.

13. A cross bulk acoustic resonator (XBAR) device comprising:
a substrate;
a bottom multilayer van der Waals (vdW) material provided on the substrate;
a piezoelectric layer provided on the bottom multilayer vdW material;
a top multilayer vdW material provided on the piezoelectric layer; and
one or more electrodes provided on the top multilayer vdW material.

14. The XBAR device of claim 13, further comprising a dielectric layer provided between the substrate and the bottom multilayer vdW material.

15. The XBAR device of claim 13, wherein:
the one or more electrodes are configured to induce a shear acoustic wave in the piezoelectric layer; and
the top multilayer vdW material and the bottom multilayer vdW material are configured to trap the shear acoustic wave within the piezoelectric layer.

16. An acoustic gyroscope device comprising:
a substrate;
a sensing acoustic resonator provided on the substrate;
a dielectric layer provided over the sensing acoustic resonator;
a bottom multilayer van der Waals (vdW) material provided on the dielectric layer;
a driving acoustic resonator provided on the bottom multilayer vdW material; and
a top multilayer vdW material provided over the driving acoustic resonator.

17. The acoustic gyroscope device of claim 16, wherein:
the sensing acoustic resonator is configured to propagate a longitudinal acoustic wave; and
the driving acoustic resonator is configured to propagate a shear acoustic wave.

18. The acoustic gyroscope device of claim 17, wherein the driving acoustic resonator is configured to convert the shear acoustic wave into the longitudinal acoustic wave that propagates through the dielectric layer to the sensing acoustic resonator.

19. The acoustic gyroscope device of claim 18, wherein the top multilayer vdW material and the bottom multilayer vdW material are configured to:
trap the shear acoustic wave within the driving acoustic resonator; and
pass the longitudinal acoustic wave to the sensing acoustic resonator.

20. A wireless device comprising one or more acoustic devices selected from the group consisting of: a surface acoustic wave (SAW) device, a guided SAW device, a bulk acoustic wave (BAW) device, a cross bulk acoustic resonator (XBAR) device, and an acoustic gyroscope device.
